(19) United States
(12) Patent Application Publication
(10) Pub. No.: US 2023/0321944 A1
(43) Pub. Date: Oct. 12, 2023

(54) DISPLAY PANEL, DISPLAY DEVICE AND METHOD FOR MANUFACTURING DISPLAY DEVICE

(71) Applicant: TIANMA ADVANCED DISPLAY TECHNOLOGY INSTITUTE (XIAMEN) CO., LTD., Xiamen (CN)

(72) Inventors: Zhenyu JIA, Xiamen (CN); Aowen LI, Xiamen (CN); Kerui XI, Xiamen (CN); Tianyi WU, Xiamen (CN); Xiaoxiang HE, Xiamen (CN); Yingteng ZHAI, Xiamen (CN); Xiaoli LIU, Xiamen (CN); Yukun HUANG, Xiamen (CN); Shaorong YU, Shanghai (CN); Feng QIN, Shanghai (CN)

(73) Assignee: TIANMA ADVANCED DISPLAY TECHNOLOGY INSTITUTE (XIAMEN) CO., LTD., Xiamen (CN)

(21) Appl. No.: 18/322,614

(22) Filed: May 24, 2023

(30) Foreign Application Priority Data
Mar. 31, 2023 (CN) 202310341232.2

(51) Int. Cl. B32B 3/26; B32B 15/04; B32B 3/30

(52) U.S. Cl. CPC B32B 3/266; B32B 3/30; B32B 15/04; B32B 2457/20

(57) ABSTRACT

A display panel, a display device and a method for manufacturing a display device are provided. The display panel includes: a display area and a non-display area, at least a part of the non-display area is located on a side of the display area in a first direction; and the non-display area includes at least one first metal portion and a first marker, and the first marker extends through the first metal portion. With the display panel, display device and method, whether an actual grinding line reaches the target grinding line can be determined in real time.

This application claims priority to Chinese Patent Application No. 202310341232.2, titled “DISPLAY PANEL, DISPLAY DEVICE AND METHOD FOR MANUFACTURING DISPLAY DEVICE”, filed on Mar. 31, 2023 with the China National Intellectual Property Administration, which is hereby incorporated by reference in its entirety.

### FIELD

The present disclosure relates to the field of display technology, and more particularly, to a display panel, a display device and a method for manufacturing a display device.

### BACKGROUND

A frameless display device generally refers to a display device with an extremely narrow frame. Since the proportion of the display area in the frameless display device is large, the frameless display device is becoming increasingly popular. Due to the frameless design, the complexity of the manufacturing process of the display device is increased, and it is more likely to cause errors in the manufacturing process of the display device, affecting the manufacturing accuracy. Hence, a problem to be solved urgently is how to improve the accuracy of manufacturing the display device.

### SUMMARY

A display panel, a display device and a method for manufacturing a display device are provided according to embodiments of the present disclosure, which can improve the efficiency of grinding an edge of a display panel.

In one embodiment, a display panel is provided, the display panel includes: a display area and a non-display area, where at least a part of the non-display area is located on a side of the display area in a first direction, the non-display area includes at least one first metal portion and a first marker, and the first marker extends through the first metal portion.

In another embodiment, a display device is provided, which includes the display panel according to the embodiments of the present disclosure.

In yet another embodiment, a method for manufacturing a display device is provided, where the method is performed to manufacture the display device according to the embodiments of the present disclosure. The method includes: providing a display panel; positioning a target grinding line according to the first marker; and grinding an edge of the non-display area facing away from the display area in the first direction until reaching the target grinding line.

With the display panel, the display device and method for manufacturing a display device according to the present disclosure, the first marker that extends through the first metal portion is arranged in the non-display area, and the target grinding line can be determined according to the position of the first marker, to determine whether the actual grinding line reaches the target grinding line in real time, to simplify the grinding process, thus improving the grinding efficiency.

### BRIEF DESCRIPTION OF THE DRAWINGS

In order to more clearly explain the embodiments of the present disclosure, the drawings used in the description of the embodiments are briefly introduced hereinafter. It is apparent that the drawings in the following description illustrate some embodiments of the present disclosure.

FIG. 1 is a schematic structural diagram of a display panel according to an embodiment of the present disclosure;

FIG. 2 is a schematic structural diagram of a first metal portion of a display panel according to an embodiment of the present disclosure;

FIG. 3 is a schematic structural diagram of a first metal portion of a display panel according to another embodiment of the present disclosure;

FIG. 4 is a schematic structural diagram of a first metal portion of a display panel according to another embodiment of the present disclosure;

FIG. 5 is a schematic structural diagram of a first metal portion of a display panel according to another embodiment of the present disclosure;

FIG. 6 is a schematic structural diagram of a first metal portion of a display panel according to another embodiment of the present disclosure;

FIG. 7 is a schematic structural diagram of a first metal portion of a display panel according to another embodiment of the present disclosure;

FIG. 8 is a schematic structural diagram of a first metal portion of a display panel according to another embodiment of the present disclosure;

FIG. 9 is a schematic structural diagram of a first metal portion of a display panel according to another embodiment of the present disclosure;

FIG. 10 is a schematic structural diagram of a first metal portion of a display panel according to another embodiment of the present disclosure;

FIG. 11 is a schematic structural diagram of a first metal portion of a display panel according to another embodiment of the present disclosure;

FIG. 12 is a schematic structural diagram of a display panel according to another embodiment of the present disclosure;

FIG. 13 is a schematic structural diagram of a display panel according to another embodiment of the present disclosure;

FIG. 14 is a schematic structural diagram of a first metal portion of a display panel according to another embodiment of the present disclosure;

FIG. 15 is a schematic structural diagram of a first metal portion of a display panel according to another embodiment of the present disclosure;

FIG. 16 is a schematic structural diagram of a first metal portion of a display panel according to another embodiment of the present disclosure;

FIG. 17 is a schematic structural diagram of a first metal portion of a display panel according to another embodiment of the present disclosure;

FIG. 18 is a schematic structural diagram of a first metal portion of a display panel according to another embodiment of the present disclosure;

FIG. 19 is a schematic structural diagram of a first metal portion of a display panel according to another embodiment of the present disclosure;

FIG. 20 is a schematic structural diagram of a first metal portion of a display panel according to another embodiment of the present disclosure;

FIG. 21 is a schematic structural diagram of a first metal portion of a display panel according to another embodiment of the present disclosure;

FIG. 22 is a schematic structural diagram of a first metal portion of a display panel according to another embodiment of the present disclosure;

FIG. 23 is a schematic structural diagram of a first metal portion of a display panel according to another embodiment of the present disclosure;

FIG. 24 is a schematic structural diagram of a display panel according to another embodiment of the present disclosure;

FIG. 25 is a schematic structural diagram of a display panel according to another embodiment of the present disclosure;

FIG. 26 is a schematic structural diagram of a display device according to an embodiment of the present disclosure;

FIG. 27 is a schematic structural diagram of a display device according to another embodiment of the present disclosure;

FIG. 28 is a flow chart of a method for manufacturing a display device according to an embodiment of the present disclosure;

FIG. 29 is a flow chart of a method for manufacturing a display device according to another embodiment of the present disclosure; and

FIG. 30 is a flow chart of a method for manufacturing a display device according to another embodiment of the present disclosure.

Reference signs are listed as follows:

| | | | |
|---|---|---|---|
| 1 | First metal portion | 2 | First marker |
| 21 | First sub-line | 22 | Second sub-line |
| 23 | First hollow portion | 24 | Second hollow portion |
| 25 | First interval | 26 | First end |
| 27 | Second end | 28 | Third sub-line |
| 29 | Positioning hole | | |
| 100 | Display device | 110 | Display panel |
| 120 | Flexible circuit board | | |
| AA | Display area | NA | Non-display area |
| BD | Bonding area | D1 | First direction |
| D2 | Second direction | D3 | Third direction |
| D4 | Fourth direction | P1 | First point |
| P2 | Second point | | |

### DETAILED DESCRIPTION OF EMBODIMENTS

Embodiments of the present disclosure will be described in detail below. In the following detailed description, numerous specific details are set forth in order to provide a thorough understanding of the present disclosure. Embodiments of the present disclosure may be practiced without some of these specific details. The following description of the embodiments may provide a better understanding of the present disclosure by showing examples thereof.

It should be noted that, the embodiments and the features in the embodiments in the present disclosure may be combined with each other unless conflict exist otherwise. The embodiments will be described in detail below in conjunction with the drawings.

The relationship terms such as “first”, “second” and the like are may be used herein to distinguish one entity or operation from another, rather than to necessitate or imply that an actual relationship or order exists between the entities or operations. Furthermore, the terms such as “include”, “comprise” or any other variants thereof means to be non-exclusive. Hence, a process, a method, an article or a device including a series of elements include not only the disclosed elements but also other elements that are not clearly enumerated, or further include inherent elements of the process, method, article or device. Unless expressively limited, the statement “including a...” does not exclude the case that other similar elements may exist in the process, method, article or device other than enumerated elements.

It should be understood that, when describing the structure of a component, when a layer or a region is referred to as being “on” or “over” another layer or another region, it may indicate that being directly on another layer or another region. In one embodiment, other layers or regions may also include between it and another layer or another region. In addition, if the component is flipped, the layer or the region will be “below” or “beneath” another layer or another region.

In addition, hereinafter, the term “and/or” is only an association relationship describing associated objects, which indicates that there may be three relationships. For example, A and/or B, which may indicate three following scenarios: A exists alone, A and B exist simultaneously, and B exists alone. In addition, the character “/” in this article generally indicates that the contextual objects are in an “or” relationship.

It should be understood that in this embodiment of the present disclosure, “B corresponding to A” indicates that B is associated with A, and B may be determined based on A. However, it should also be understood that “B is determined based on A” does not necessarily imply that B is determined only based on A, rather, B may also be determined based on A and/or other information.

It has been found that when manufacturing a frameless display device or display device with a narrow frame, a part of the circuit of the display device is usually bonded to the display panel in the form of a flexible circuit board, and the flexible circuit board is bent to the backlight side of the display panel to reduce the proportion of the non-display area. Before the bonding connection, in order to facilitate the smooth alignment of the flexible circuit board and the display panel, the edge of the display panel is ground first. During the grinding process, it is required to determine whether the actual grinding line reaches the target grinding line. Due to the limitation of measuring tools, it is generally required to remove the display panel from the grinding equipment to measure the grinding degree to the actual grinding line, to determine whether the actual grinding line reaches the target grinding line. Since it is required to suspend grinding and remove the display panel every time when it is determined whether the actual grinding line reaches the target grinding line, the grinding process is more complicated, resulting in a lower grinding efficiency, affecting the production efficiency of the display device.

In view of the above problems, a display panel, a display device and a method for manufacturing a display device are provided according to the present disclosure. The display panel includes a display area and a non-display area. The non-display area includes a first metal portion and a first marker extending through the first metal portion. The first metal portion can be multiplexed as an electrical connection portion on the display panel used for bonding connection with the flexible circuit board. In this way, the first metal portion, on one hand, can be used as a marker for positioning the grinding line, on the other hand, can be used for bonding connection between the display panel and the flexible circuit board.

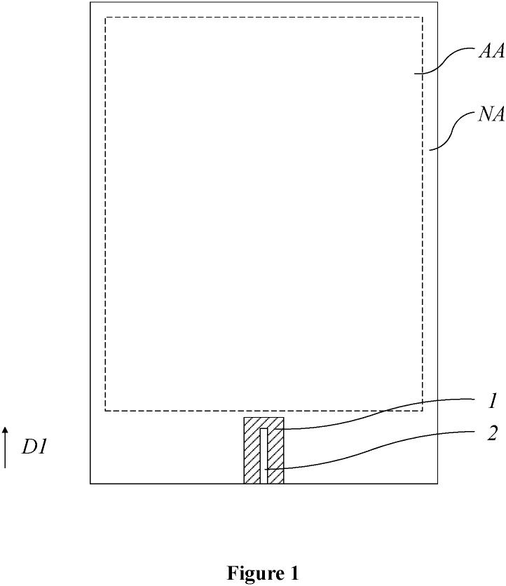

FIG. 1 is a schematic structural diagram of a display panel according to an embodiment of the present disclosure.

Referring to FIG. 1, a display panel is provided according to an embodiment of the present disclosure. The display panel includes a display area AA and a non-display area NA, at least a part of the non-display area NA is located on a side of the display area AA in a first direction D1. The non-display area NA includes at least one first metal portion 1 and at least one first marker 2, and the first marker 2 extends through the first metal portion 1.

The display panel in the embodiment of the present disclosure may be an organic light-emitting diode (OLED) display panel, a liquid crystal (LCD) display panel or a micro light-emitting diode (Micro-LED) display panel. The display panel includes a display area AA and a non-display area NA. The display area AA of the display panel can emit light. At least a part of the non-display area NA is located on a side of the display area AA in the first direction D1, i.e., the non-display area NA may partially surround the display area AA.

The non-display area NA includes a first metal portion 1 and a first marker 2. The first metal portion 1 may be used for electrical connection between the display panel and other components of the display device. For example, the first metal portion 1 may be used for bonding connection of the flexible circuit board. The first metal portion 1 may also be used only to form the first marker 2. Since the first marker 2 extends through the first metal portion 1, a positional relationship between an actual grinding line and the first marker 2 may be observed in real time during the grinding process. As the first marker 2 has been prepared on the first metal portion 1 before grinding, the first marker 2 may reflect the position of the target grinding line. For example, the first marker 2 may be prepared at the target grinding line, the relative positional relationship between the actual grinding line and the target grinding line may be obtained based on the positional relationship between the actual grinding line and the first marker 2, and whether the actual grinding line reaches the target grinding line can be determined. Since the positional relationship between the actual grinding line and the first marker 2 can be observed in real time, whether the actual grinding line reaches the target grinding line can be determined in real time, and the process of taking off the panel from the grinding equipment to measure the distance between the actual grinding line and the target grinding line can be eliminated (if it is not necessary), to simplify the grinding steps and improving the grinding efficiency, thus improving the production efficiency of the display device. In addition, since the positional relationship between the actual grinding line and the first marker 2 can be observed in real time, the grinding accuracy can be improved and the possibility of excessive grinding can be reduced, to lower the risk of damaging the display panel due to excessive grinding.

It is to be noted that the first marker 2 extends through the first metal portion 1 in a thickness direction of the first metal portion 1, that is, a direction perpendicular to the plane of the display panel as shown in FIG. 1. Therefore, in a case that the first marker 2 is formed in the first metal portion 1, the position of the first marker 2 may be observed based on the difference in light transmittance between the first metal portion 1 and the first marker 2. For example, in a case that the first metal portion 1 is made of an opaque metal material, the light transmittance at the first marker 2 extending through the first metal portion 1 is higher, and the position of the first marker 2 may be determined based on the brightness of the transmission light.

During the grinding process, the non-display area NA is first ground from the edge of the display panel. Then, the grinding is performed gradually from the side of the non-display area NA away from the display area AA to the display area AA in the first direction D1 until reaching the position of the target grinding line determined by the first marker 2.

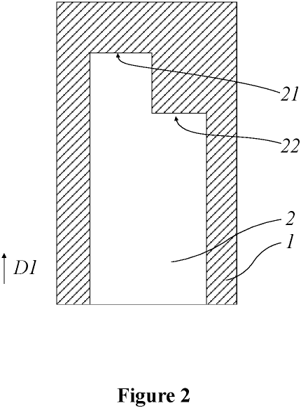

FIG. 2 is a schematic structural diagram of a first metal portion of a display panel according to an embodiment of the present disclosure.

Further, referring to FIG. 2, an outline of the first marker 2 includes a first sub-line 21 and a second sub-line 22. A distance from the first sub-line 21 to the display area AA is different from a distance from the second sub-line 22 to the display area AA in the first direction D1, and the first sub-line 21 and the second sub-line 22 are located in different straight lines.

Each of the first sub-line 21 and the second sub-line 22 is a part of the outline of the first marker 2. Both the first sub-line 21 and the second sub-line 22 may be used to determine whether the actual grinding line reaches the target grinding line. The distances from the first sub-line 21 and the second sub-line 22 to the display area AA are different from each other, i.e., the distances from the first sub-line 21 and the second sub-line22 to the edge of the non-display area NA (the edge of the display panel for grinding) are different from each other. In different scenarios, the first sub-line 21 and the second sub-line 22 may be used as sub-markers of the first marker 2 corresponding to different target grinding lines, to meet different grinding requirements. During grinding, the distances from the actual grinding line to the first sub-line 21 and the second sub-line 22 are also different from each other. In addition, since the distance from the first sub-line 21 to the edge of the display panel is greater than that of the second sub-line 22, in a case that the position of the first sub-line 21 is used as the target grinding line and when the actual grinding line reaches the second sub-line Line 22, it can be determined that the actual grinding line is close to the target grinding line, to be on the alert or take measures to reduce the risk of excessive grinding, e.g. reducing the grinding feed amount per time unit. As a result, the grinding accuracy can be improved.

It is to be noted that the first sub-line 21 and the second sub-line 22 are located on different straight lines. The actual grinding line does not reach the first sub-line21 and the second sub-line 22 simultaneously during the grinding process. The first sub-line 21 and the second sub-line 22 each correspond to a straight line, and the first sub-line 21 and the second sub-line 22 can form different sub-markers of the first marker 2.

During the grinding process, the non-display area NA is first ground from the edge of the display panel, and grinding is performed gradually from the side of the non-display area NA away from the display area AA to the display area AA in the first direction D1, until reaching the position of the target grinding line determined by the first sub-line 21 or the second sub-line 22. When the grinding is completed, if the first sub-line 21 or the second sub-line 22 is not ground off, the first sub-line21 or the second sub-line22 that has not been ground off may be used for alignment and positioning between the display panel and the flexible circuit board in the embodiment of the present disclosure, to bond the display panel to the flexible circuit board in the embodiment of the present disclosure.

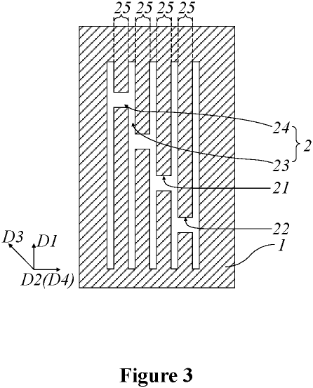

FIG. 3 is a schematic structural diagram of a first metal portion of a display panel according to another embodiment of the present disclosure.

Further, referring to FIG. 3, the first marker 2 includes at least two first hollow portions 23 extending in the first direction D1 and arranging in the second direction D2, and at least two second hollow portions 24. The second hollow portion 24 is connected between adjacent first hollow portions 23. The distances from the at least two second hollow portions 24 to the display area AA in the first direction D1 are different from each other. The first sub-line 21 is a part of an outline of one of the second hollow portions 24, and the second sub-line 22 is a part of an outline of the other second hollow portion 24, where the second direction D2 intersects with the first direction D1.

The first hollow portions 23 include multiple hollow structures extending in the first direction D1 and arranging in the second direction D2. The second hollow portion 24 is located between adjacent first hollow portions 23. The first hollow portion 23 and the second hollow portion 24 may be communicated with each other to form a whole. The distances from multiple second hollow portions 24 to the display area AA are different from each other, where a part of the outline of one second hollow 24 forms the first sub-line 21, and a part of the outline of the other second hollow 24 forms the second sub-line 22, and the distances from the two second hollow portions 24 to the display area AA are different from each other. The direction in which the second hollow portion 24 extends may be parallel to the second direction D2 or may intersect with the second direction D2. Since the first sub-line 21 and the second sub-line 22 respectively correspond to parts of outlines of different second hollow portions 24, the distance between the actual grinding line and the target grinding line can be visually determined during the grinding process. In addition, during the grinding process, when the actual grinding line is close to the target grinding line and grinding is performed at the second hollow portion 24, a part of the first metal portion 1 is removed at the second hollow portion 24, and the hollow structure formed by the second hollow portion 24 is located at the actual grinding line. Once the first metal portion 1 is warped at the actual grinding line, it will also be removed, to lower the risk that the first metal portions 1 is warped or broken at the actual grinding line. For example, both the first hollow portions 23 and the second hollow portions 24 may be strip-shaped, the second hollow portion 24 extends in the second direction D2, and the part of the outline of the second hollow portion 24 parallel to the second direction D2 corresponds to the first sub-line 21 or the second sub-line 22.

During the grinding process, the non-display area NA is first ground from the edge of the display panel, grinding is performed gradually from the side of the non-display area NA away from the display area AA to the display area AA in the first direction D1. At least a part of each first hollow portion 23 is gradually ground off, and at least one of the multiple second hollow portions 24 is gradually ground off, and there may be second hollow portions 24 that have not been ground. Grinding is performed gradually until the actual grinding line reaches the position of the target grinding line determined by one of the second hollow portions 24. Since the length of the first hollow portion 23 in the first direction D1 gradually decreases during the grinding process, the relative position of the actual grinding line and the target grinding line can be observed visually. Whether the actual grinding line is close to the target grinding line can be determined according to the length of the first hollow portion 23 to determine when to end the grinding process, and the second hollow portion 24 assists to determine the grinding position accurately with the first hollow portion.

Further referring to FIG. 3, a first interval 25 is located between adjacent first hollow portions 23, and the at least two second hollow portions 24 are located at different first intervals 25.

In a case that the number of the first hollow portions 23 is at least three and the number of the second hollow portions 24 is at least two, the first interval 25 is located between adjacent first hollow portions 23, and at least two second hollow portions 24 are located in different first intervals 25. In other words, the orthographic projections of at least two second hollow portions 24 in the first direction D1 are not overlapped, the position of the target grinding line can be easily determined, and the second hollow portions 24 with different distances to the display area AA are less likely to interfere the observation.

Further referring to FIG. 3, the second hollow portions 24 are arranged in the third direction D3, where the third direction D3 intersects with the first direction D1 and the third direction D3 intersects with the fourth direction D4. The fourth direction D4 is parallel to the edge of the display panel adjacent to the first metal portion.

During the grinding process, both the actual grinding line and the target grinding line may be parallel to the fourth direction D4. Since the second hollow portions 24 are arranged in the third direction D3, and the third direction D3 intersects with the first direction D1, and the third direction D3 intersects with the fourth direction D4, the distances from any adjacent second hollow portions 24 to the display area AA in the third direction D3 have the same difference therebetween, and such difference may be used as a reference for preliminarily determining the position of the actual grinding line. During the grinding process, when the target grinding line is determined based on a part of the outline of a second hollow portion 24, the distance between the actual grinding line and the target grinding line may be preliminarily determined based on the number of second hollow portions 24 between the actual grinding line and the target grinding line. In a case that the distance between the actual grinding line and the target grinding line is less than the difference between the distances from adjacent second hollow portions 24 to the display area AA, it indicates that the actual grinding line is close to the target grinding line, to be on the alert or take measures to reduce the risk of excessive grinding, e.g. reducing the grinding feed amount per time unit. It is to be noted that the second direction D2 may be parallel to the fourth direction D4. In one embodiment, the second direction D2 may also intersect with the fourth direction D4.

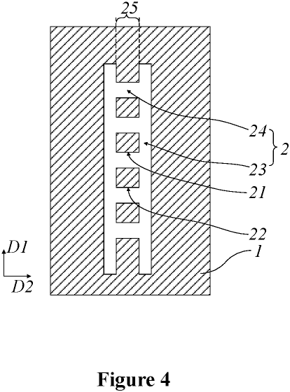

FIG. 4 is a schematic structural diagram of a first metal portion of a display panel according to another embodiment of the present disclosure.

Further referring to FIG. 4, a first interval 25 is located between adjacent first hollow portions 23, and at least two second hollow portions 24 are located at the same first interval 25.

In a case that the number of the first hollow portions 23 is at least two, and the number of the second hollow portions 24 is at least two, adjacent first hollow portions 23 are spaced by the first interval 25, and at least two second hollow portions 24 are located in the same first interval 25. In other words, the orthographic projections of at least two second hollow portions 24 in the first direction D1 are overlapped. During the grinding process, when the target grinding line is determined by a part of the outline of a second hollow portion 24, the distance between the actual grinding line and the target grinding line can be preliminarily determined based on the number of second hollow portions 24 between the actual grinding line and the target grinding line. In a case that the distance between the actual grinding line and the target grinding line is less than the difference between distances from adjacent second hollow portions 24 to the display area AA, since the two second hollow portions 24 are located at the same first interval 25, the distance between the target grinding line and the actual grinding line can be observed and determined more visually and accurately, which is more beneficial to determine when to end the grinding process.

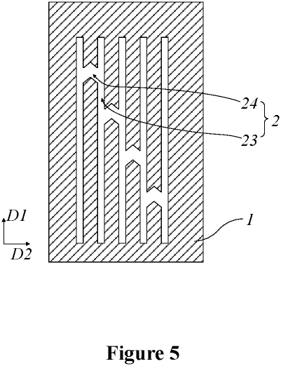

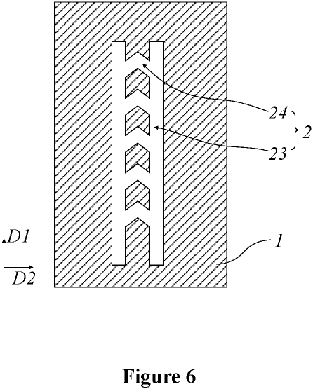

FIG. 5 is a schematic structural diagram of a first metal portion of a display panel according to another embodiment of the present disclosure. FIG. 6 is a schematic structural diagram of a first metal portion of a display panel according to another embodiment of the present disclosure.

Further referring to FIG. 5 and FIG. 6, the second hollow portion 24 includes a combination of one or more of zigzag lines, curved lines, and wavy lines.

The second hollow portion 24 may be a strip structure including a combination of one or more of zigzag lines, curved lines, and wavy lines. The distance from the outline of each second hollow portion 24 to the display area AA changes along the outline. A combination of one or more of zigzag lines, curved lines, and wavy lines has a size in the first direction D1. In the grinding process, if the target grinding line is determined as a part of the outline of a second hollow portion 24, when the actual grinding line is close to the target grinding line, the outline of the second hollow portion 24 has not yet been ground. As the grinding progresses, the outline of the second hollow portion is gradually ground off. The grinding process from a point that the outline of the second hollow portion 24 begins to be ground to a point that the outline of the second hollow portion 24 is completely ground may be used as a buffer process before the end of the grinding, and may also be used for providing redundancy for determining when to end the grinding process. Hence, by observing the change of the ground outline of the second hollow portion 24, it is more accurate to determine when to end the grinding process, to improve the grinding accuracy.

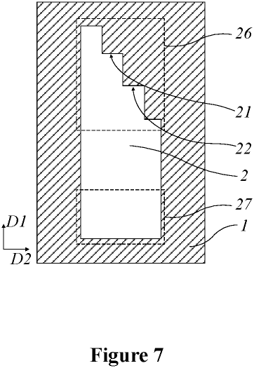

FIG. 7 is a schematic structural diagram of a first metal portion of a display panel according to another embodiment of the present disclosure.

Further referring to FIG. 7, the first marker 2 includes a first end 26 and a second end 27 opposite to each other in the first direction D1. At least one of an outline of the first end and an outline of the second end includes a zigzag line, and each of the first sub-line 21 and the second sub-line 22 is a part of the zigzag line.

The first marker 2 may also be formed by a whole hollow structure. In the first direction D1, one of the first end 26 and the second end 27 of the first marker 2 is close to the display area AA, and the other is away from the display area AA. One of the first end 26 and the second end 27 of the first marker 2 includes a zigzag line, and each of the first sub-line 21 and the second sub-line 22 is a part of the zigzag line. For example, in a case that the distances from the first sub-line 21 and the second sub-line 22 to the display area AA are different from each other and the zigzag line bends back and forth, the zigzag line may form a zigzag shape or a stepped shape, and the first sub-line 21 and the second sub-line 22 are two line segments of the zigzag line that are parallel to each other. In a case that the first end 26 and/or the second end 27 include a zigzag line, the first marker 2 forms a single hollow structure with a simple shape, which reduces the difficulty in manufacturing the first metal portion 1 while facilitating the determination of the distance between the actual grinding line and the target grinding line in real-time. The first sub-line 21 and the second sub-line 22 may be arranged in a third direction D3, where the third direction D3 intersects with the first direction D1, the third direction D3 intersects with a fourth direction D4, and the fourth direction D4 is parallel to the edge of the display panel adjacent to the first metal portion.

Further referring to FIG. 7, at least one of the first sub-line 21 and the second sub-line 22 extends in the second direction D2, and the second direction D2 intersects with the first direction D1.

During the grinding process, the actual grinding line may be parallel to the second direction D2. At least one of the first sub-line 21 and the second sub-line 22 extends in the second direction D2, that is, at least one of the first sub-line 21 and the second sub-line 22 is parallel to the actual grinding line (the edge of the display panel). In this way, the distance between the actual grinding line and the first sub-line 21 or the distance between the actual grinding line and the second sub-line 22 may be determined more visually, which facilitates the determination of the distance between the actual grinding line and the target grinding line in real-time during the grinding process.

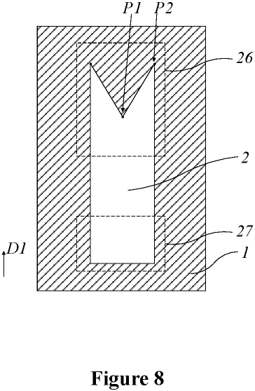

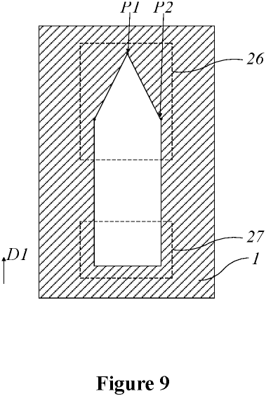

FIG. 8 is a schematic structural diagram of a first metal portion of a display panel according to another embodiment of the present disclosure. FIG. 9 is a schematic structural diagram of a first metal portion of a display panel according to another embodiment of the present disclosure.

Further referring to FIG. 8 and FIG. 9, the first marker 2 includes a first end 26 and a second end 27 opposite to each other in the first direction D1. The first end 26 or the second end 27 includes a first point P1 and second points P2 located on two sides of the first point P1 respectively, the second points P2 are connected to the first point P1 through a linear part of the outline of the first marker 2. The distances from the two points P2 to the display area AA are both less or greater than the distance from the first point P1 to the display area AA.

The distance between the actual grinding line and the target grinding line may be determined by the first end 26 or the second end 27 of the first marker 2. With the first point P1 and second points P2 located on two sides of the first point P1 respectively, two line segments are formed between the two second points P2 and the first point P1 by connecting the second points P2 to the first point P1 through linear parts of the outline of the first marker 2, both of which intersect with the first direction D1. The distances from the two second points P2 to the display area AA are both less or greater than the distance from the first point P1 to the display area AA, and the two line segments form a V-shaped or inverted V-shaped zigzag line. The position of the target grinding line may be determined at the point of the line segments close to the display area AA. During the grinding process, when the actual grinding line is close to the target grinding line, the actual grinding line will gradually replace the zigzag line formed by the two line segments. Hence, the distance between the actual grinding line and the target grinding line can be accurately determined according to the remaining parts of the two line segments, which can reduce the error between the actual grinding line and the target grinding line and improve the grinding accuracy. A connecting line between the two second points P2 intersects with the first direction D1, and the first point P1 is located on one side of the connecting line. The connecting line between the two second points P2 may be used to determine the position of the target grinding line. In this case, the connecting line between the two second points P2 is parallel to the edge of the display panel.

Further referring to FIG. 8, for example, if the distance from the second point P2 to the display area is greater than that of the first point P1, the position of the target grinding line may be determined by the connecting line formed by the two second points P2 of the first marker 2. During the grinding process, when the actual grinding line reaches the first point P1, it may be determined that the actual grinding line is close to the target grinding line. In the first direction D1, the area from the first point P1 to the connection line of the second points P2 may be used a buffer before the end of grinding and may also provide redundancy for determining when to end the grinding process. Therefore, the grinding accuracy can be improved.

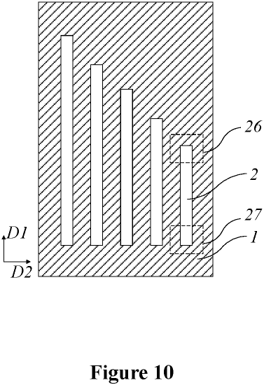

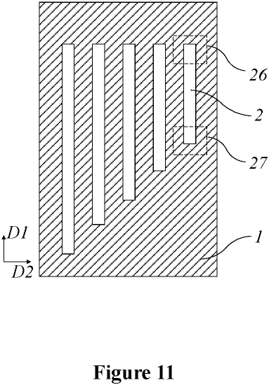

FIG. 10 is a schematic structural diagram of a first metal portion of a display panel according to another embodiment of the present disclosure. FIG. 11 is a schematic structural diagram of a first metal portion of a display panel according to another embodiment of the present disclosure.

Further referring to FIG. 10 and FIG. 11, there are multiple first markers 2 arranged in the second direction D2, where the second direction D2 intersects with the first direction D1. The first markers 2 extend in the first direction D1. Each of the first markers 2 includes a first end 26 and second end 27 opposite in the first direction D1. The distances from multiple first ends 26 to the display area AA are different from each other, and/or, the distances from multiple second ends 27 to the display area AA are different from each other.

There are multiple first markers 2, where each first marker 2 corresponds to a hollow structure. The distances from the first ends 26 of the first markers 2 and/or the second ends 27 of the first markers 2 to the display area AA are different from each other. In this case, each first marker 2 may be used to determine the position of the target grinding line. The first markers 2 extend in the first direction D1 and are arranged in the second direction D2. During the grinding process, both the target grinding line and the actual grinding line may be parallel to the second direction D2, and multiple first markers 2 will not interfere with each other, and the distance between the target grinding line and the actual grinding line can be determined in real time. For example, the first marker 2 may be an elongated strip shape extending in the first direction D1, e.g. a rectangle shape.

Further referring to refer to FIG. 10, during the grinding process, the non-display area NA is first ground from the edge of the display panel, and grinding is performed gradually from the non-display area NA away from the display area AA to the display area AA in the first direction D1. At least a part of each first marker 2 will be gradually ground off, there may be a first marker 2 that has been ground off completely, and there may be a first marker 2 that has not been ground. Grinding is performed until the actual grinding line reaches the position of the target grinding line determined by the first end 26 of a first marker 2. When the display panel is bonded to the flexible circuit board in the embodiment of the present disclosure, the first end 26 of the first marker 2 that has not been completely ground off may be used for alignment and positioning between the display panel and the flexible circuit board in the embodiment of the present disclosure.

Further referring to refer to FIG. 11, during the grinding process, the non-display area NA is first ground from the edge of the display panel, and grinding is performed gradually from the non-display area NA away from the display area AA to the display area AA in the first direction D1. At least a part of at least one first marker 2 among the multiple first markers 2 is gradually ground off, there may be a first marker 2 that has not been ground. Grinding is performed until the actual grinding line reaches the position of the target grinding line determined by the second end 27 of a first marker 2. When the display panel is bonded to the flexible circuit board in the embodiment of the present disclosure, the first end 26 of the first marker 2 that has not been completely ground off may be used for alignment and positioning between the display panel and the flexible circuit board in the embodiment of the present disclosure.

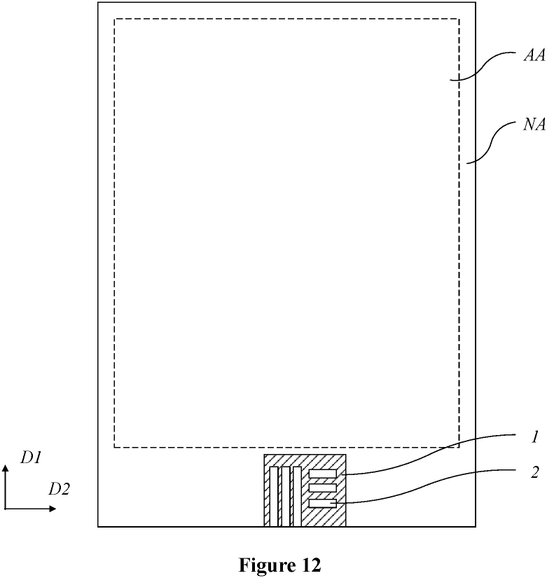

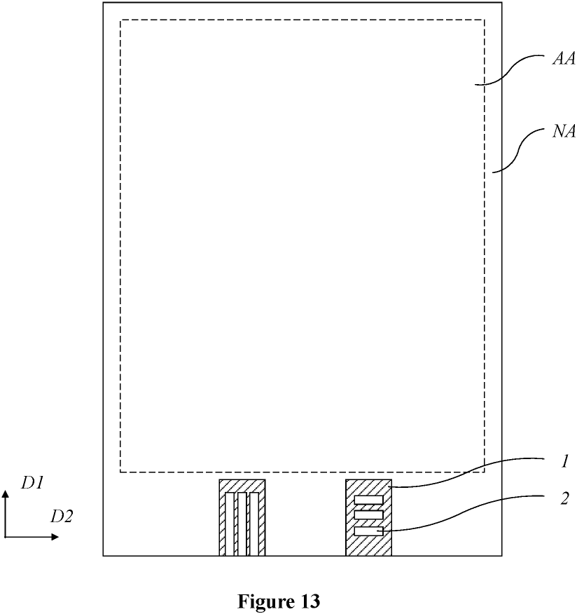

FIG. 12 is a schematic structural diagram of a display panel according to another embodiment of the present disclosure. FIG. 13 is a schematic structural diagram of a display panel according to another embodiment of the present disclosure.

Further referring to FIGS. 12 and 13, there are multiple first markers 2, at least some of the first markers 2 are arranged in the first direction D1 and extend in the second direction D2, at least some of the first markers 2 are arranged in the second direction D2 and extend in the first direction D1. The first direction D1 intersects with the second direction D2.

Both the first markers 2 extending in the first direction D1 and the first markers 2 extending in the second direction D2 may have a strip-shaped hollow structure. The first markers 2 extending in the second direction D2 are arranged in the first direction D1, and the distances to the display area are different from each other, which may be used to determine the position of the target grinding line. During the grinding process, the non-display area NA is firstly ground from the edge of the display panel, grinding is performed gradually from the side of the non-display area NA away from the display area AA to the display area AA in the first direction D1. The first markers 2 extending in the direction D1 are gradually ground, and the length of the unground portion gradually decreases, to observe the relative position between the actual grinding line and the target grinding line visually. When there are multiple first metal portions 1, the multiple first markers 2 on the same first metal portion 1 may all extend in the first direction D1 or all extend in the second direction D2. In one embodiment, one first metal portion 1 includes both the first markers 2 extending in the first direction D1 and the first markers 2 extending in the second direction D2.

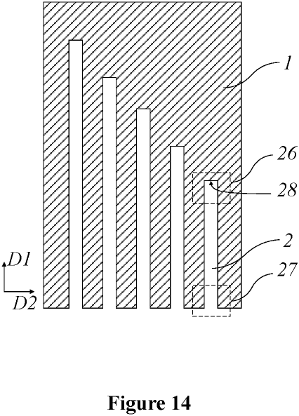

FIG. 14 is a schematic structural diagram of a first metal portion of a display panel according to another embodiment of the present disclosure.

Further, referring to FIG. 14, the distance from the first end 26 to the display area AA is less than the distance from the second end 27 to the display area AA. The outline of the first end 26 includes a third sub-line 28, the distances from at least two third sub-lines 28 to the display area AA are different from each other; the second end 27 extends to the edge of the display panel adjacent to the first metal portion 1.

The first end 26 is closer to the display area AA than the second end 27, and the distance from the first end 26 to the display area AA is less than the distance from the second end 27 to the display area AA. The first end 26 is used to determine the position of the target grinding line. In one embodiment, the outline of the first end 26 includes the third sub-line 28. The second end 27 extends to the edge of the display panel adjacent to the first metal portion 1, and the hollow structure of the first marker 2 communicates with the periphery of the first metal portion 1, which can simplify the manufacturing process of the first metal portion 1. In addition, during the grinding process, at least parts of multiple first markers 2 are gradually ground off in an order of distances from the first ends 26 thereof to the display area AA from large to small, and the distance between the target grinding line and the actual grinding line can be determined visually by observing the number of remaining first markers 2 that have not been ground off.

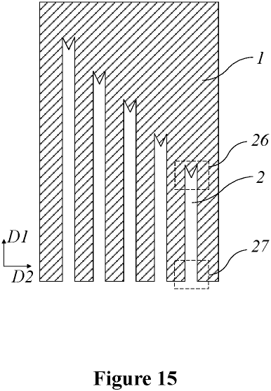

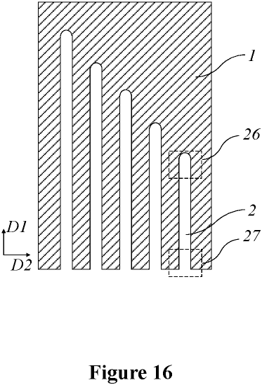

FIG. 15 is a schematic structural diagram of a first metal portion of a display panel according to another embodiment of the present disclosure. FIG. 16 is a schematic structural diagram of a first metal portion of a display panel according to another embodiment of the present disclosure.

Further referring to FIGS. 15 and 16, the first marker 2 further includes a first end 26 and a second end 27 opposite in the first direction D1, the outline of the first end 26 or the outline of the second end 27 includes a combination of one or more of zigzag lines, curved lines, and wavy lines.

In the first marker 2, the outline of the first end 26 or the second end 27 includes a combination of one or more of zigzag lines, curved lines, and wavy lines. A combination of one or more of zigzag lines, curved lines, and wavy lines has a size in the first direction D1. For example, the first end 26 of the first marker 2 includes a V-shaped or inverted V-shaped zigzag line, or the first end 26 of the first marker 2 includes a curved line. During the grinding process, the target grinding line is determined by the outline of the first end 26 of a first marker 2. Before the actual grinding line reaches the target grinding line, the actual grinding line will first approach the first end 26 of another the first marker 2, and the distance from the first end 26 of the first marker 2 to the display area AA is greater than the distance from the target grinding line to the display area AA. In this process, the relative position of the actual grinding line and the target grinding line may be preliminarily determined. As the grinding progresses, when the actual grinding line is close to the first end 26 of the first marker 2 that determines the target grinding line, it can be visually determined that the actual grinding line is close to the target grinding line. In this case, the outline of the first end 26 of the first marker 2 has not been ground yet. As the grinding progresses, the outline of the first end 26 of the first marker 2 is gradually ground off. The grinding process from a point that the outline of the first end 26 of the first marker 2 begins to be ground to a point that the outline of the first end 26 of the first marker 2 is completely ground off may be used for a buffer before the end of the grinding and may also be used for providing redundancy for determining when to end the grinding process. Hence, the relative position of the actual grinding line and the target grinding line can be determined accurately.

In the above grinding process, multiple first markers 2 may assist in preliminarily determining the relative position of the actual grinding line and the target grinding line. The shape of the first end 26 of the first marker 2 may assist in further determining the relative position of the actual grinding line to the target grinding line. In the process of determining the relative position of the actual grinding line to the target grinding line, the multiple first markers 2 and the shape of the first end 26 of the first marker 2 are used corporately to improve the accuracy of determination and the grinding process. In other words, the first markers of different lengths and the outline of the first end of the first marker are used as two reference for different accuracy requirements, and the position for determining the target grinding line may be selected according to different accuracy requirements.

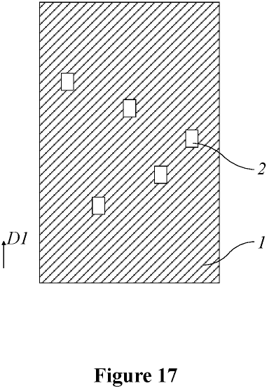

FIG. 17 is a schematic structural diagram of a first metal portion of a display panel according to another embodiment of the present disclosure.

Further referring to FIG. 17, there are multiple first markers 2, and the distances from the multiple first markers 2 to the display area AA are different from each other.

The first marker 2 may also be a hole structure in the first metal portion 1, where the distances from multiple hole structures to the display area AA are different from each other. During the grinding process, the position of the target grinding line may be determined according to the hole structures of the first marker 2. In addition, in an order of the distances from the first ends 26 to the display area AA from large to small, at least some of multiple first markers 2 are gradually ground off. In this way, the target grinding line and the actual grinding line may be observed visually by observing the number of remaining first markers 2 that are not completely ground, to preliminarily determine the distance between the target grinding line and the actual grinding line.

During the grinding process, the non-display area NA is first ground from the edge of the display panel, and grinding is performed gradually from the side of the non-display area NA away from the display area AA to the display area AA in the first direction D1. At least one of the multiple first markers 2 is gradually ground off, and there may be first markers 2 that have not been ground off. Grinding is performed gradually until the actual grinding line reaches the position of the target grinding line determined by a first marker 2. When the display panel is bonded to the flexible circuit board in the embodiment of the present disclosure, the first markers 2 that have not been ground off can be used for the alignment and positioning between the display panel and the flexible circuit board in the embodiment of the present disclosure.

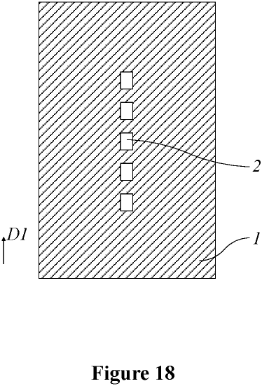

FIG. 18 is a schematic structural diagram of a first metal portion of a display panel according to another embodiment of the present disclosure.

Further referring to FIG. 18, multiple first markers 2 are arranged in the first direction D1.

Since the multiple first markers 2 are arranged in the first direction D1, the space occupied by the first markers 2 on the first metal portion 1 in a direction vertical to the first direction D1 can be reduced, to facilitate the miniaturization of the first metal portion 1 and further reducing the space occupied by the non-display area NA. In this way, it is beneficial to provide a display panel with a narrow frame in the embodiment of the present disclosure.

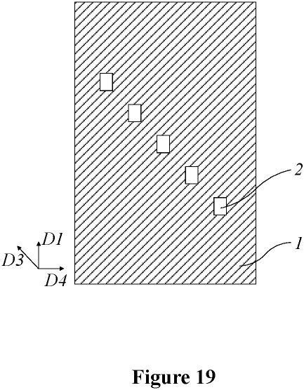

FIG. 19 is a schematic structural diagram of a first metal portion of a display panel according to another embodiment of the present disclosure.

Further referring to FIG. 19, multiple first markers 2 are arranged in the third direction D3, where the third direction D3 intersects with the first direction D1, and the third direction D3 intersects with the fourth direction D4. The fourth direction D4 is parallel to the edge of the display panel adjacent to the first metal portion 1.

During the grinding process, both the actual grinding line and the target grinding line may be parallel to the fourth direction D4. Since the first markers 2 are arranged in the third direction D3, the third direction D3 intersects with the first direction D1, and the third direction D3 intersects with the fourth direction D4, distances from any adjacent first markers 2 to the display area AA in the third direction D3 have the same difference therebetween, and such difference may be used as a reference for preliminarily determining the actual grinding line position. During the grinding process, when the target grinding line is determined by a first marker 2, the distance between the target grinding line and the actual grinding line may be preliminarily determined according to the number of unground first markers 2 between the actual grinding line and the target grinding line. When there is no unground first marker 2 between the actual grinding line and the target grinding line, it indicates that the actual grinding line is close to the target grinding line, to be on the alert or take measures to reduce the risk of excessive grinding, e.g. reducing the grinding feed amount per time unit.

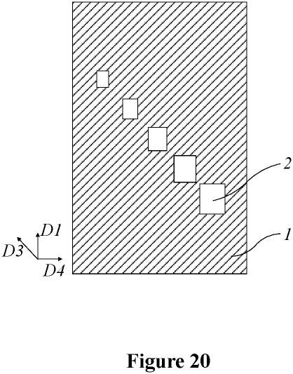

FIG. 20 is a schematic structural diagram of a first metal portion of a display panel according to another embodiment of the present disclosure.

Further referring to FIG. 20, the orthographic projections of multiple first markers 2 on a plane where the display panel is located have the same shape, and the orthographic projections of at least two first markers 2 have different sizes.

During the grinding process, since the sizes of the orthographic projections of the multiple first markers 2 are different from each other, it is easier to observe and distinguish the first marker 2 that is used to determine the target grinding line, to visually determine the distance between the target grinding line and the actual grinding line. In addition, when there is no unground first marker 2 between the actual grinding line and the target grinding line, the actual grinding line and the outline of the first marker 2 may be observed. By observing the changes of the actual grinding line and the outline of the first marker 2, the distance between the target grinding line and the actual grinding line can be determined accurately to improve the grinding accuracy. Different sizes of the first markers 2 correspond to different grinding accuracies, and the first markers 2 may be selected appropriately according to the process requirements of the display panel to realize the proper grinding accuracy.

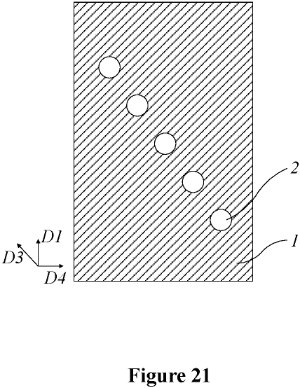

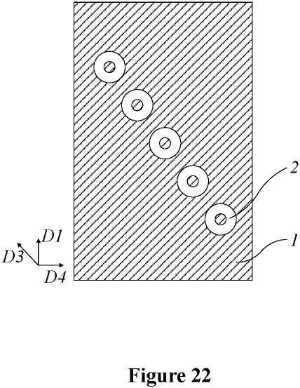

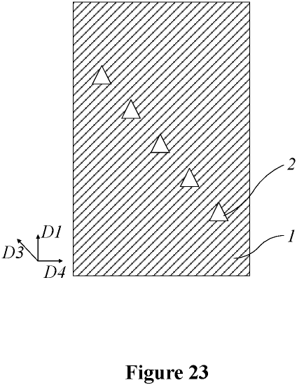

FIG. 21 is a schematic structural diagram of a first metal portion of a display panel according to another embodiment of the present disclosure. FIG. 22 is a schematic structural diagram of a first metal portion of a display panel according to another embodiment of the present disclosure. FIG. 23 is a schematic structural diagram of a first metal portion of a display panel according to another embodiment of the present disclosure.

Further referring to FIG. 21 to FIG. 23 and in combination with FIG. 19, the outline of the first marker 2 is a rotationally symmetrical shape.

After the rotationally symmetrical first marker 2 is rotated around its own rotation center by an angle (greater than 0° and less than or equal to 180°), the shape of the rotationally symmetrical first marker 2 after rotation may coincides with the shape before rotation, and the position of the rotation center of the first marker 2 may be determined. The distances from the rotation centers of the multiple first markers 2 to the display area AA are different from each other. During the grinding process, the position of the target grinding line and the distance between the actual grinding line and the target grinding line can be determined by the positions of the rotation centers of the first markers 2.

Further referring to FIG. 21 to FIG. 23 in combination with FIG. 19, the outline of the first marker 2 includes a combination of one or more of rings, circles, polygons, and polygons with rounded corners.

The Rings, circles, polygons and polygons with rounded corners may be used to form a rotationally symmetrical shape. The rotation centers of ring and circle are the positions of their own circle centers, and the rotation centers of polygons and polygons with rounded corners are the positions of their own circumscribed circle centers. In this way, the complexity of the first marker 2 can be simplified to facilitate the processing and manufacture of the first marker 2. For example, the outline of the first marker 2 may include a regular triangle, a rectangle or a rhombus.

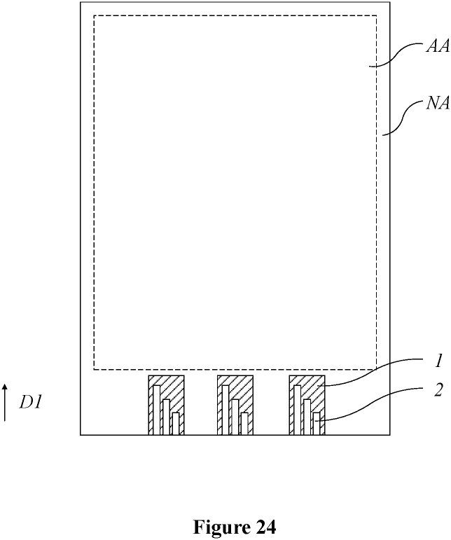

FIG. 24 is a schematic structural diagram of a display panel according to another embodiment of the present disclosure.

Further referring to FIG. 24, there are multiple first metal portions 1, and the multiple first metal portions 1 are arranged along the edge of the display panel.

There are multiple first metal portions 1, and multiple first markers 2 are provided on each of the first metal portions 1. In the same first metal portion 1, the distances from the multiple first markers 2 to the display area AA are different from each other. In the first metal portions 1, the distances from at least two first markers 2 to the display area AA are the same. During the grinding process, multiple first markers 2 with the same distance from the display area AA can be used to determine the position of the target grinding line simultaneously. In addition, multiple first markers 2 with the same distance from the display area AA may also be simultaneously used to determine the distance between the actual grinding line and the target grinding line, to lower the possibility of the actual grinding line being inclined with respect to the target grinding line. The first metal portion 1 should be located at the edge of the display panel, and the distance between the actual grinding line and the target grinding line can be determined by the first marker 2 of the first metal portion 1 when grinding the edge of the display panel.

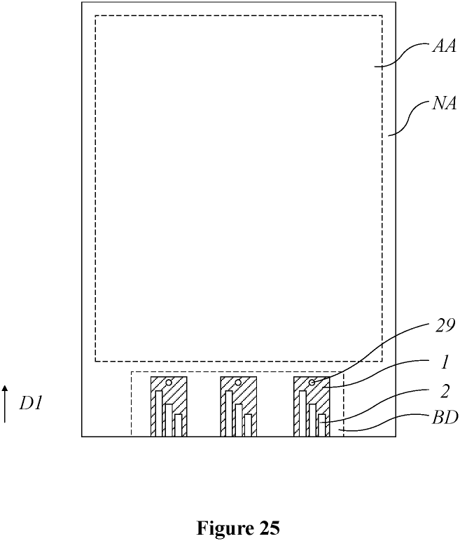

FIG. 25 is a schematic structural diagram of a display panel according to another embodiment of the present disclosure.

Further referring to FIG. 25, the non-display area NA includes a bonding area BD, and the bonding area BD includes an electrical connection portion. The first metal portion 1 may be multiplexed as the electrical connection portion, and the electrical connection portion is electrically connected to the flexible circuit board.

In the bonding area BD of the display panel, the display panel is usually electrically connected to the flexible circuit board through the electrical connection portion. In the embodiment of the present disclosure, the first metal portion 1 may be multiplexed as an electrical connection portion and be electrically connected to the flexible circuit board. In this way, the difficulty of patterning can be reduced when manufacturing the metal layer corresponding to the first metal portion 1, and the space of the non-display area NA can be fully utilized, which facilitates preparation of the display panel with a narrow frame in the embodiment of the present disclosure. Further, a positioning hole 29 may be provided on the first metal portion 1 for alignment and positioning when the electrical connection portion is electrically connected to the flexible circuit board. The positioning hole 29 should be located between the first markers 2 and the display area AA.

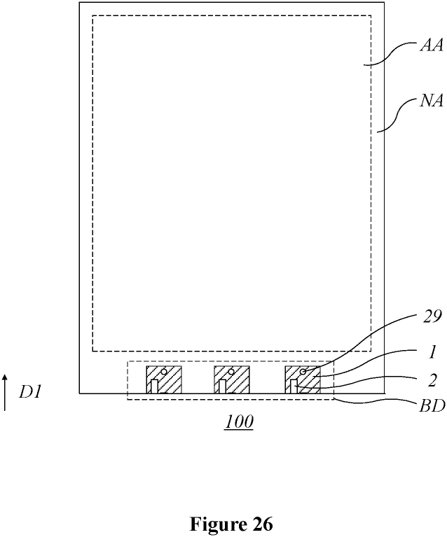

FIG. 26 is a schematic structural diagram of a display device according to an embodiment of the present disclosure.

Referring to FIG. 26, a display device 100 is further provided according to an embodiment of the present disclosure, the display device 100 includes the display panel 110 according to the foregoing embodiments of the present disclosure. According to the embodiment of the present disclosure, the display device 100 may be any product or component with realistic functions such as a mobile phone, a tablet computer, a television, a monitor, a laptop, a digital photo frame, and a navigator.

According to the embodiment of the present disclosure, when manufacturing the display device 100 by using the display panel 110 according to the foregoing embodiment of the present disclosure, it is required to grind the display panel 110, where the non-display area NA is first ground from the edge of the display panel, and grinding is performed gradually from the side of the non-display area NA away from the display area AA to the display area AA in the first direction D1, until the actual grinding line reaches the position of the target grinding line determined by a first marker 2.

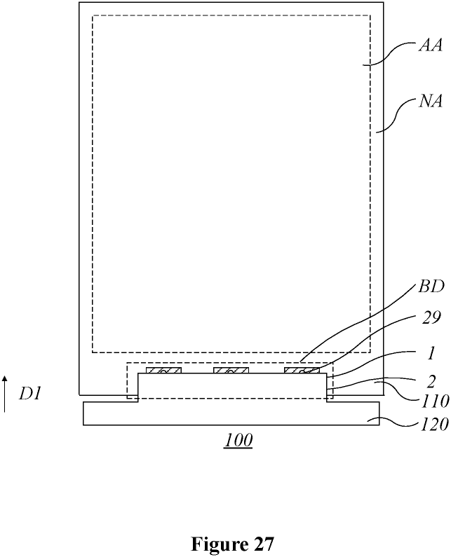

FIG. 27 is a schematic structural diagram of a display device according to another embodiment of the present disclosure.

Further, referring to FIG. 27 in combination with FIG. 23, according to an embodiment of the present disclosure, the display device 100 further includes a flexible circuit board 120, and the flexible circuit board 120 is electrically connected to the first metal portion 1.

According to an embodiment of the present disclosure, the display device 100 may further include a chip, and the chip may be arranged on the flexible circuit board 120. After the display panel 110 is bonded to the flexible circuit board 120, the display panel 110 is electrically connected to the chip to control the display panel 110 to display light. The chip will be bent along with the flexible circuit board 120 to the side of the substrate of the display panel 110 away from the array base. Before bonding, the display panel 110 has been ground. During binding, the display panel 110 and the flexible circuit board 120 may be aligned through the positioning hole 29 on the first metal portion 1, and the display panel 110 and the flexible circuit board 120 can be in a satisfied electrical contact state after bonding.

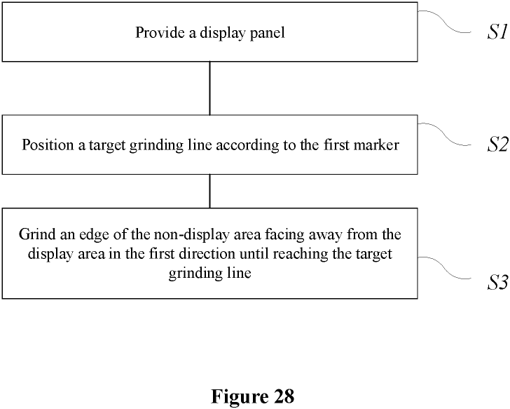

FIG. 28 is a flow chart of a method for manufacturing a display device according to an embodiment of the present disclosure.

Referring to FIG. 28, a method for manufacturing the display device 100 is further provided according to an embodiment of the present disclosure, which is used to manufacture the display device 100 according to the foregoing embodiments of the present disclosure.

According to an embodiment of the present disclosure, a method for manufacturing the display device 100 includes the following steps S1 to S3.

In S1, a display panel 110 is provided.

The display panel 110 may be the display panel 110 according to the foregoing embodiments of the present disclosure, where a final product of the display panel may be provided directly, or the display panel 110 may be manufactured.

In S2, a position of a target grinding line is determined according to a first marker 2.

Among multiple first markers 2, a position corresponding to one of the first markers 2 is selected as the position of the target grinding line. It is to be noted that each of the multiple first markers 2 may be used to determine the position of the target grinding line.

In S3, an edge of the non-display area NA facing away from the display area AA is ground in the first direction D1 until reaching the target grinding line.

When grinding the edge of the non-display area NA facing away from the display area AA in the first direction D1, the actual grinding line should be parallel to the target grinding line. During the grinding process, the distance between the actual grinding line and the target grinding line is determined in real time by observing the first markers 2 that have not been completely ground, until the actual grinding line reaches the target grinding line. Hence, in the present disclosure, the grinding efficiency can be significantly improved and the risk of excessive grinding can be reduced.

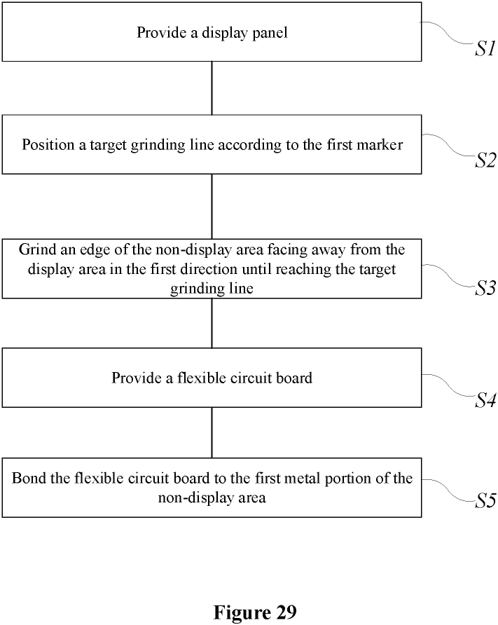

FIG. 29 is a flow chart of a method for manufacturing a display device according to another embodiment of the present disclosure.

Further referring to FIG. 29, according to the embodiment of the present disclosure, a method for manufacturing the display device 100 further includes the following steps S4 to S5.

In S4, a flexible circuit board 120 is provided.

A final product of the flexible circuit board 120 may be provided directly, or the flexible circuit board 120 may be manufactured.

In S5, the flexible circuit board 120 is bonded to the first metal portion 1 of the non-display area NA.

The flexible circuit board 120 is provided with a bonding terminal at a position corresponding to the first metal portion 1. The bonding terminal may be connected to the first metal portion 1 by welding to realize the bonding connection.

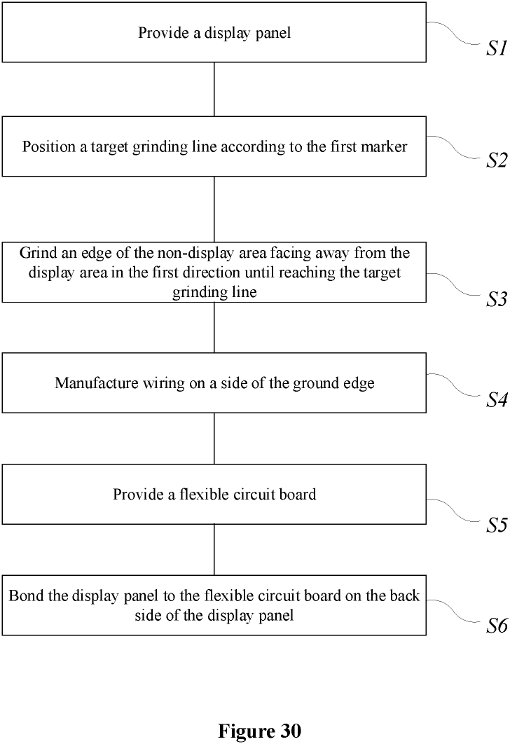

FIG. 30 is a flow chart of a method for manufacturing a display device according to another embodiment of the present disclosure.

Further referring to FIG. 30, according to the embodiment of the present disclosure, a method for manufacturing a display device 100 further includes the following steps S4 to S6.

In S4, wiring is manufactured on a side of the ground edge.

A part of the wiring of the display device 100 is manufactured on a side of the ground edge of the display panel 110, to meet the manufacturing requirements of the frameless display.

In S5, a flexible circuit board 120 is provided.

In S6, the display panel 110 is bonded to the flexible circuit board 120 on the back side of the display panel 110.

In other words, the side of the ground edge may be used for manufacturing the wiring and subsequent display assembling. Hence, high-accuracy grinding and grinding detecting provided in the present disclosure can better improve the accuracy control.

In view of the above, a display panel, a display device and a method for manufacturing a display device are provided according to the embodiments of the present disclosure. The first marker that extends through the first metal portion is arranged in the non-display area, and the target grinding line may be determined according to the position of the first marker, to determine whether the actual grinding line reaches the target grinding line in real time, which can simplify the grinding process and improve the grinding efficiency.

What is claimed is:

1. A display panel, comprising:
a display area; and
a non-display area, wherein
at least a part of the non-display area is located on a side of the display area in a first direction, and
the non-display area comprises at least one first metal portion and at least one first marker, and the first marker extends through the first metal portion.

2. The display panel according to claim 1, wherein
an outline of the first marker comprises a first sub-line and a second sub-line;
a distance from the first sub-line to the display area in the first direction is different from a distance from the second sub-line to the display area in the first direction; and
the first sub-line and the second sub-line are located in different straight lines.

3. The display panel according to claim 2, wherein
the first marker comprises at least two first hollow portions and at least two second hollow portions, the at least two first hollow portions each extends in the first direction and are arranged in a second direction, each of the at least two second hollow portions is connected between adjacent first hollow portions;
distances from the at least two second hollow portions to the display area in the first direction are different from each other; and
the first sub-line is a part of an outline of one of the second hollow portions, and the second sub-line is a part of an outline of another second hollow portion, and wherein
the second direction intersects with the first direction.

4. The display panel according to claim 3, wherein a first interval is located between adjacent first hollow portions, and the at least two second hollow portions are located at different first intervals.

5. The display panel according to claim 4, wherein
the second hollow portions are arranged in a third direction, the third direction intersects with the first direction, the third direction intersects with a fourth direction, and the fourth direction is parallel to an edge of the display panel adjacent to the first metal portion.

6. The display panel according to claim 3, wherein a first interval is located between two adjacent first hollow portions, and the at least two second hollow portions are located at the same first interval.

7. The display panel according to claim 3, wherein the second hollow portion comprises a combination of one or more of zigzag lines, curved lines, and wavy lines.

8. The display panel according to claim 2, wherein
the first marker comprises a first end and a second end opposite to each other in the first direction;
at least one of an outline of the first end and an outline of the second end comprises a zigzag line, and each of the first sub-line and the second sub-line is a part of the zigzag line.

9. The display panel according to claim 2, wherein at least one of the first sub-line and the second sub-line extends in a second direction, and the second direction intersects with the first direction.

10. The display panel according to claim 1, wherein
the first marker comprises a first end and a second end opposite to each other in the first direction;
the first end or the second end comprises a first point and second points located on two sides of the first point respectively, each of the second points is connected to the first point through a linear part of an outline of the first marker; and
distances from the two second points to the display area are both less or greater than a distance from the first point to the display area.

11. The display panel according to claim 1, wherein
a number of the first marker is at least two, at least two first markers are arranged in a second direction, the second direction intersects with the first direction;
the at least two first markers each extends in the first direction;
the at least two first marker comprises first ends and second ends opposite to each other in the first direction; and
distances from the first ends to the display area are different from each other, and/or distances from the second ends to the display area are different from each other.

12. The display panel according to claim 11, wherein
the distances from the first ends to the display area are less than the distances from the second ends to the display area;
an outline of each of the first end comprises a third sub-line;
distances from at least two third sub-lines to the display area are different from each other; and
the second ends extend to an edge of the display panel adjacent to the first metal portion.

13. The display panel according to claim 1, wherein the first marker further comprises a first end and a second end opposite to each other in the first direction, and an outline of the first end or an outline of the second end comprises a combination of one or more of zigzag lines, curved lines, and wavy lines.

14. The display panel according to claim 1, wherein a number of the first marker is at least two, distances from at least two first markers to the display area are different from each other.

15. The display panel according to claim 14, wherein the at least two first markers are arranged in the first direction; or
wherein the at least two first markers are arranged in a third direction, the third direction intersects with the first direction, the third direction intersects with a fourth direction, and the fourth direction is parallel to an edge of the display panel adjacent to the first metal portion.

16. The display panel according to claim 14, wherein orthographic projections of the at least two first markers on a plane where the display panel is located have the same shape, and the orthographic projections of at least two of the at least two first markers have different sizes.

17. The display panel according to claim 1, wherein an outline of the first marker comprises a rotationally symmetrical shape; or
wherein an outline of the first marker comprises a combination of one or more of rings, circles, polygons, and polygons with rounded corners.

18. The display panel according to claim 1, wherein a number of the first metal portion is at least two, and at least two first metal portions are arranged along an edge of the display panel.

19. The display panel according to claim 1, wherein the non-display area comprises a bonding area,
the first metal portion is multiplexed as an electrical connection portion of the bonding area, and is electrically connected to a flexible circuit board.

20. A display device, comprising a display panel, wherein
the display panel comprises:
a display area; and
a non-display area, and wherein
at least a part of the non-display area is located on a side of the display area in a first direction, and
the non-display area comprises at least one first metal portion and a first marker, and the first marker extends through the first metal portion.

21. A method for manufacturing a display device, wherein the method comprises:
providing a display panel, wherein the display panel comprises a display area and a non-display area, and at least a part of the non-display area is located on a side of the display area in a first direction, the non-display area comprises at least one first metal portion and a first marker, and the first marker extends through the first metal portion;
positioning a target grinding line according to the first marker; and
grinding an edge of the non-display area facing away from the display area in the first direction until reaching the target grinding line.
